(19) United States
(12) Patent Application Publication
(10) Pub. No.: US 2004/0021142 A1
(43) Pub. Date: Feb. 5, 2004

(54) Light emitting diode device

(76) Inventor: Li-Hsin Kuo, Taipei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/207,152

(22) Filed: Jul. 30, 2002

(51) Int. Cl. H01L 27/15

(52) U.S. Cl. 257/79

(57) ABSTRACT

A light emitting diode is made by a compound semiconductor in which light emitting from an active region with a multi-quantum well structure. The active region is sandwiched by InGaAlP-based lower and upper cladding layers. Emission efficiency of the active region is improved by adding light and electron reflectors in the light emitting diode. These InGaAlP-based layers are grown epitaxially by Organometallic Vapor-Phase Epitaxy (OMVPE) on a GaAs substrate with a thin thickness to improve the thermal gradient, reliability, brightness quality, and performance in light emitting.

### BACKGROUND OF THE INVENTION

1. Field of the Invention

The present invention generally to a method for forming a semiconductor light emitting diode device, and in particular to a method forming a compound semiconductor light emitting diode device on a thin semiconductor substrate.

2. Description of the Prior Art

A light emitting diode (LED) is widely used in various fields such as an optical communication and optical information processing as a light source, which permits low power consumption, a high efficiency and a high reliability. Particularly, compound semiconductors such as GaP (green), GaAsP (yellow, orange, red), and GaAlAs (red) are widely used as the materials of the light emitting layers within a visible wavelength. Region.

However, the light emitting efficiency of each of GaP and GaAsP, which are indirect transition type semiconductors, is as low as about 0.5% even if a transparent substrate is used to eliminate the influence of absorption. On the other hand, GaAlAs permits an efficiency of about 8% at 660 nm. However, the efficiency is affected by the indirect transition in a shorter wavelength region. For example, the light emitting efficiency at a wavelength of 635 nm is about 1%.

Among the III-V group compound semiconductor mixed crystals excluding nitrides, the InGaAlP mixed crystal exhibits the largest energy gap of the direct transition type, and attracts attentions as a material of a light emitting element which emits light having wavelengths of 0.5 to 0.6 micron. Particularly, an LED comprising a GaAs substrate and an InGaAlP layer whose lattice is aligned with the GaAs substrate is expected to emit light of green to red wavelength regions with a high brightness. Even in the Led of this kind, however, the light emitting efficiency is not sufficiently high in the short wavelength region.

FIG. 1 shows a schematic diagram of a conventional device structure of a light emitting diode 100. In this figure, the device structure 100 comprises a double hetero-structure (DH) with the quaternary In_{0.5}(Ga₁₋ₓAlₓ)_{0 5}P alloy system grown on a n-GaAs substrate 100 with thickness is thicker than about 350 um. The issue of the conventional prior art is thickness of n-GaAs substrate 102. In generally, the n-GaAs substrate 102 is obtained from the manufacturing company, and preprocess such as a polishing process or an etching process is must to be utilized prior to the other layers that are formed on the n-GaAs substrate 102 to obtain an applied thickness of the n-GaAs substrate 102 for light emitting diode device 100, such as 180 um. Nevertheless, no matter the polishing process or etching process, the n-GaAs substrate 102 cannot obtained uniformity and reliability material, and the thermal gradient within the n-GaAs substrate 102 is poor to let the emitting efficiency is reduced.

Then, also referring to FIG. 1, the LED 100 is a p-n junction with a forward bias to inject holes from a p-type cladding layer 108 and electrons from an n-type cladding layer 104 into an active region. The active layer 106 emits visible light due to the recombination of the electrons and holes in this region. Electrons and holes are injected as minority carriers across the active region and they recombine either by radiative recombination or non-radiative recombination. The emitting wavelength of the InGaAlP-based LED 100 can be adjusted by changing the Al composition of the In_{0 5}(Ga₁₋ₓAlₓ)_{0 5}P alloy in the active layer 106, having a right energy gap to meet a specific wavelength of emission light. For instance, a shorter wavelength such as in yellow or yellow-green color requires a higher Al composition in the In_{0.5}(Ga₁₋ₓAlₓ)_{0.5}P active layer 106 for light emission. The thickness of the active layer 106 is reduced in a thick active region due to a low carrier density. A typical thickness of the active region is around 0.3 to 0.5 um. The active region is an area for the carrier injection and recombination to generate light. The requirement on material quality in the active region is very high for achieving a high efficient light emission. This requires a very low background of intrinsic impurity in the active region, which may reduce the concentration of non-radiative recombination center. A high doping background of the active region is mainly contributed from a high density of deep traps in the active region, which may cause non-radiative recombination in the process of light emission. A clean and low impurity reaction in the reaction chamber is essential for the growth of the active region. Typically, the In_{0.5}(Ga₁₋ₓAlₓ)_{0.5}P active layer 106 is an un-doped layer, either n- or p-type, with a doping concentration of about 5*10¹⁵ to 1*10¹⁷/cm². On the other hand, the background of the doping level in the active is increased with an increase in the composition of Al in the active region. This is due to an increase on the impurity level at a higher Al concentration in the active region. For a shorter wavelength, therefore, the increase of Al composition in the active region associates with a reduction on the internal quantum efficiency of emission light. As described above, a higher Al concentration in the active region associates with an increase on the deep level causing non-radiative recombination in the light emitting layer that decrease the efficiency of the light emission.

The n- 104 and p-type 108 cladding layers provides a source of injection carriers and have an energy gap higher than that of the active layer 106 for the confinement of the injecting carriers and emitting light. These cladding layer 104, 108 require a good conductivity and suitable doping concentration to supply enough injected carriers into the active region to achieve a high efficiency in light emission. The thickness of the In_{0.5}(Ga₁₋ₓAlₓ)_{0.5}P layer should be thick enough to prevent the carriers in the active region flowing back to the cladding layer, but not too thick to affect the emission efficiency of the LED 100. As a result, a large portion of injected carriers overflow into the cladding layers, and current leakage occurs due to the non-radiative recombination of these overflow carriers. Consequently, the radiation efficiency in the conventional LED 100 containing double hetero-structure (DH) degrades as the wavelength of the device becoming shorter.

Following the p-type cladding layer 108, there is a current diffusion layer 110 for spreading out the emitting light efficiently. The current spreading layer 110 requires a semiconductor to be transparent to the wavelength of the emission light from the active region. In addition, the window layer 112 needs to spread current efficiently into the active 106 and cladding layer 108, which requires a high doping level and thick window layer 112. Then, a metal contact 114 on the top of the window layer 112 and another metal contact 116 on the bottom of the GaAs substrate 102.

According to abovementioned, the efficiency of the light emitting of the GaAs substrate 102 will be affected by the thickness. Another disadvantage for the conventional LED structure is that the yellow and green light with higher light emitting efficiency is difficult to obtain.

### SUMMARY OF THE INVENTION

It is an object of this invention to provide a, GaAs substrate with thin thickness and with a misorientation angle that is higher than 15 degree toward <111>A to increase the brightness performance for light emitting diode device.

It is a further object of this invention to improve the reliability of the light emitting diode to increase the quality and light brightness.

It is still another object of this invention to reduce the process to form semiconductor light emitting diode device.

It is yet object of this invention to improve the thermal gradient of the whole GaAs substrate to increase the heat transfer of light emitting diode device.

According to abovementioned objects, an AlGaAs based light re-emitting layer, an InGaAlP-based light emitting layer, and a GaP—, AlGaP—, or AlGaAs-based window layer are grown epitaxially by Organometallic Vapor-Phase Epitaxy (OMVPE) on a GaAs substrate with thin thickness about 150 to about 250 um, preferably about 210 um. In addition, an electron reflector containing In_{y}(Ga₁₋ₓAlₓ)_{1-y}P/In_{0 5}(Ga₁₋ₓAlₓ)_{0 5}P superlattice, an InGaAlP-based lattice gradient layer are utilized in the light emitting diode for improvement of quantum efficiency of light emission, and film quality of In_{0.5}(Ga₁₋ₓAlₓ)_{0.5}P/GaP hetero-structure. The efficiency of the light emitting diode is also depending on the alignment of p-n junction, which is related to the doping levels and profiles of the n- and p-cladding layers. A gradient doping profile or a doping profile with a lower doping level nears the multi-quantum well (MQW) and a higher doping level away from the MQW for a better alignment of the p-n junction.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is schematic representation of light emitting diode device structure in accordance with a conventional prior art techniques;

FIG. 2 is schematic representation of the light emitting diode device structure in accordance with a structure disclosed herein; and

FIG. 3 is a schematic representation of the light emitting diode device structure in accordance with a structure disclosed herein.

### DESCRIPTION OF THE PREFERRED EMBODIMENT

Some sample embodiments of the invention will now be described in greater detail. Nevertheless, it should be recognized that the present invention can be practiced in a wide range of other embodiments besides those explicitly described, and the scope of the present invention is expressly not limited except as specified in the accompanying claims.

The emitting color of the InGaAlP-based can be adjusted by changing the Al composition of the In_{0 5}(Ga₁₋ₓAlₓ)_{0.5}P alloy in the active layer, having a right energy gap to meet a specific wavelength of emission light. The In_{0.5}(Ga₁₋ₓAlₓ)_{0.5}P alloy in the active region tends to have ordered structure leading to a decrease on the width of the band gap. A high concentration of Al in the active region is required to obtain the same desirable emission wavelength which associates with a higher density of impurities in the active region resulting in a lower luminescence efficiency. The origin of the ordered structure like atomic ordering or composition modulation in the semiconductor thin films arise from a localized variation in the tetragonal distortion of the lattice by the static displacement of atoms. In In_{0.5}(Ga₁₋ₓAlₓ)_{0 5}P alloy system, In (indium) has a larger tetrahedral covalent radius than Ga or Al atom. Thus, it is possible that the difference in the tetrahedral covalent radii produces clustering of like species, which in turn introduce local dilations and contractions of the lattice. From the thermodynamic concept of spinodal decomposition, an alloy with a certain composition located in the miscibility gap of a phase diagram has an order-disorder transformation at a transition temperature. The difference for the experimental results and the predication from the thermodynamic concept may be due to a consideration in kinetic energy and surface structure for the formation of the ordered structures. From our experiments, the In_{0 5}(Ga₁₋ₓAlₓ)_{0 5}P-based thin film follows basic rule of the spinodal decomposition and tends to have a different degree of ordered structure for a growth temperature near 660 through 770° C. The light emitting diode is epitaxial deposited at a growth temperature higher than 700° C. On the other hand, the reconstructed surface of the <001> GaAs substrate has alternating tensile and compressive regions in the substrate layer developing along the <110>-type direction. Since In has a larger tetrahedral covalent radius than Ga or Al, the alternating tensile and compressive rows on the growing surface are energy favorable nucleation sites for the occupation of the In and Ga or Al atoms, respectively. This implies that the formation of the ordered structure is also strongly related to the surface structure of the substrate in addition to the factor of order-disorder significantly using a GaAs substrate with a different miscut angle. As a result, the degree of atomic ordering in the In_{0 5}(Ga₁₋ₓAlₓ)_{0.5}P layer has been reduced greatly by increasing the miscut angle of GaAs substrate. At a growth temperature, the ordered structure in the In_{0.5}(Ga₁₋ₓAlₓ)_{0 5}P alloy is considered to be a factor to lose quantum efficiency due to an increase of the Al concentration in the In_{0 5}(Ga₁₋ₓAlₓ)_{0.5}P-based active region for obtaining a certain band width of the quantum well. Therefore, the order-disorder transition temperature can be reduced below 700° C. in a In_{0.5}(Ga₁₋ₓAlₓ)_{0.5}P-based epitaxy grown on a off-cut substrate.

Furthermore, in order to improve the efficiency of light emitting of the LED, expect for the GaAs substrate is formed on the <110> surface, the thickness is of about 350 nm from the manufacturing company. Then, the substrate is performed an etching process or polishing process to form a thin enough to apply for the substrate of LED, wherein the thickness is of about 180 nm. Nevertheless, the cost for forming thin substrate with thickness from 350 nm to 180 nm is too waste; thus, in the present invention, the thickness of the substrate is of about 150 to about 250 um, preferably about 210 um, so that the cost of etching process or polishing process can be diminished and the thin substrate can be obtained in speedily. Moreover, the thermal gradient is smaller between the upper and bottom of the substrate such that the temperature can be easily controlled, and the efficiency of light emitting can be improved during the epitaxy growth of the GaAs substrate. In addition, the heat transfer is parallel to the wafer surface that is uniformly in films growth on GaAs substrate, which would improve the uniformly of thermal condition and the uniformity of the LED device made by the whole the device performance.

In addition, the quantum efficiency of the Al-containing In_{0.5}(Ga₁₋ₓAlₓ)_{0 5}P-based multi-quantum wells can be improved by increased the substrate misorientation. On a growing surface, the increase on the off-cut of the GaAs substrate toward <111>A surface exposed more cation-terminated step edges. The incorporation of adsorbed impurities is via step trapping and depends on the bonding geometry between the adsorbed impurities and the terminated steps on the growing surface. The cation-terminated step has a single bond and provides a weak adsorption site. Thus, the step trapping efficiency decreases as the misorientation of the growing surface increase toward <111>A. Therefore, the incorporation of impurity (like silicon or oxygen) species in the active region decreases as the misorientation angle increases. Those impurities such as oxygen can act as deep levels and non-radiative recombination centers in the light-emitting region that affects the light emitting efficiency in LED. In the present invention, a GaAs substrate with a thickness of about 150 to about 250 um to obtain a better thermal gradient to enhance the reliability of the substrate, further the temperature is easy to be controlled. Another advantage for the GaAs substrate with thin thickness and with a misorientation angle higher than 10 degree, preferable 15 degree, toward <111>A is that the brightness performance will be enhanced for the light-emitting diode device.

Furthermore, the quality and smoothness of the film are improved with an InGaAlP-based LED structure grown on a misoriented GaAs substrate. A process for improving the smoothness of the semiconductor layers grown by epitaxial tools like liquid phase epitaxy (LPE) or chemical vapor deposition (CVD) for the improvement of the film smoothness. In the present invention, the InGaAlP-based LED structure is grown on a off-cut GaAs substrate with a misorientaton than 10 degree by Organometallic Vapor-Phase Epitaxy (OMVPE) to improve the film's smoothness. In the preferable embodiment of the present invention, the smoothness of the LED structure increases as the misorientation angle of the substrate increases. The improvement on surface smoothness using a misoriented substrate is especially significant on the growth of III-V mismatch heterostructure such as GaP, AlGaP, and InGaAlP-based epilayer (GaP, AlGaP, or InGaAlP alloy) and the GaAs is around 0-3.6% depending on the alloy composition in the window layer.

Then, in deposition of a film on a mismatch substrate, the initial nucleation of the film tends to form islands on the substrate and the size of these islands increase as the mismatch between film and substrate increases. This leads to the formation of a high density of threading dislocations in the films and gives rise to an increase on the surface roughness of the depositing film. The high density of crystalline defects and rough film's surface can be improved with an increase on the surface nucleation sites, a decrease on the size of the nucleation islands, and a gradient change of the lattice constant in the mismatch heterostructure. An increase in film's nucleation sites and decrease in size of the nucleation islands are achieved and a misoriented GaAs substrate with an off-cut angle than 10 degree is used and inserting an InGaAlP-based intermediate layer between the window layer and the In_{0 5}(Ga₁₋ₓAlₓ)_{0.5}P-based LED epilayer. In the off-cut substrate, the step edges on the substrate increase as the misorientation angle of the substrate increases. Those step edges provide low energy sites for the nucleation of the depositing films. Therefore, a high density of small islands nucleated on an off-cut substrate leading to an increase on the film's quality and smoothness.

Furthermore, the GaAs substrate with a thickness of about 150 to about 250 um and inserting an InGaAlP-based intermediate layer between the window layer and the In_{0.5}(Ga₁₋ₓAl)_{0.5}P-based LED epilayer. In the off-cut substrate, the step edges on the substrate increase as the misorientation angle of the substrate increases. Those step edges provide low energy sites for the nucleation of the depositing films. Therefore, smaller a high density of small islands nucleated on an off-cut substrate leading to an increase on the film's quality and smoothness. The improvement on film's quality may increase the output efficiency of the emitting light in LED. In addition, the smoothness on the film's surface may increase the window on device processing such as contact fabrication and packaging of the light emitting diodes. The improvement on film's quality, efficiency of emitting light, and process window of device fabrication is achieved.

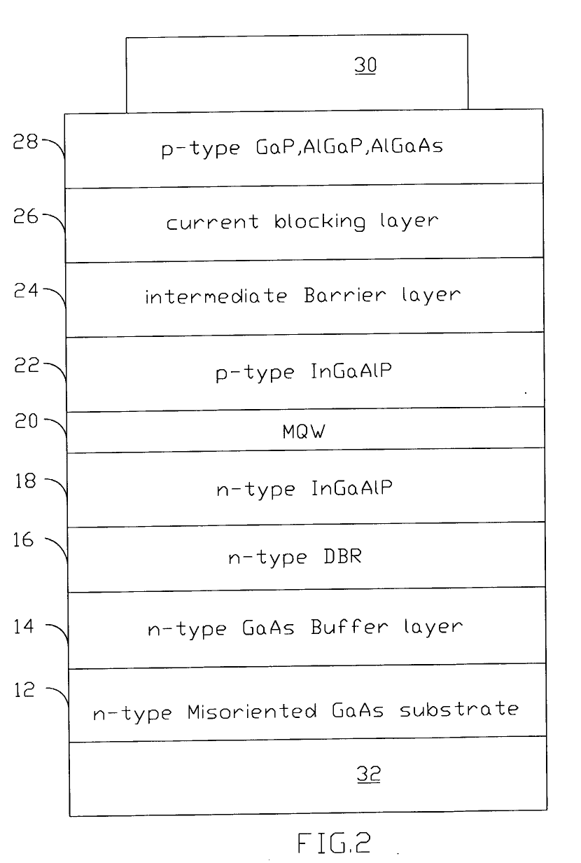

Referring to FIG. 2 shows a schematic diagram of a device structure of a light emitting diodes. In FIG. 2, the device structure comprises a light re-emitting layer and a quaternary In_{0.5}(Ga₁₋ₓAlₓ)_{0.5}P alloy grown on a n-type GaAs substrate. The device structure is constructed by a n-type GaAs buffer layer, an n-type AlAs/AlₓGa₁₋ₓAs- or In_{0 5}(Ga₁₋ₓAlₓ)_{0.5}P-based Distributed Bragg reflector (DBR), a n-type In_{0 5}(Ga₁₋ₓAlₓ)_{0 5}P lower cladding layer, a strained and un-doped In_{y}(Ga₁₋ₓAlₓ)_{1-y}P/In_{0.5}(Ga₁₋ₓAlₓ)_{0.5}P MQW, a p-type In_{0.5}(Ga₁₋ₓAlₓ)_{0.5}P upper cladding layer, a thin In_{0.5}(Ga₁₋ₓAlₓ)_{0 5}P intermediate barrier layer, a p-type GaP or AlGaAs current spreading layer, a top metal contact, and a bottom metal contact.

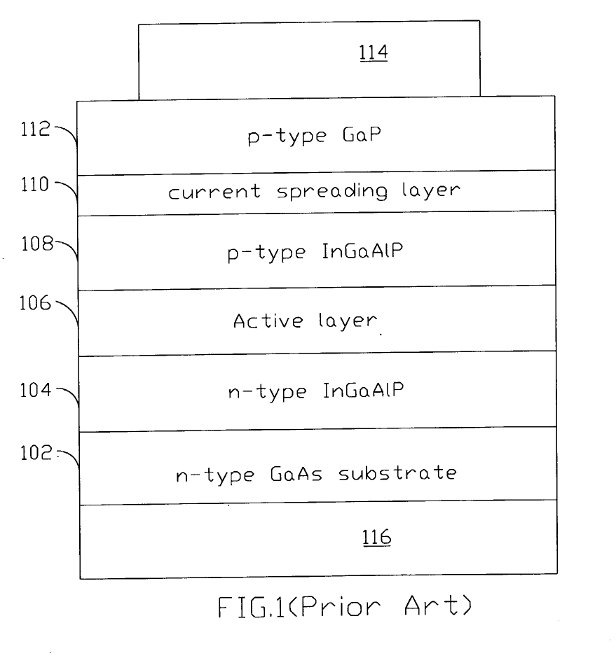

As an important feature of the present invention is that a strained In_{y}(Ga₁₋ₓAlₓ)_{1-y}P/In_{0.5}(Ga₁₋ₓAlₓ)_{0.5}P multi-quantum wells (MQW) (shown in FIG. 2) replaced the conventional InGaAlP-based active region in FIG. 1. A light re-emitting layer of n-type AlAs/AlₓGa₁₋ₓAs-, AlAs/In_{0 5}(Ga₁₋ₓAlₓ)_{0.5}P-, In_{0.5}(Ga₁₋ₓAlₓ)_{0.5}P-based DBR is placed on bottom of the In_{0 5}(Ga₁₋ₓAlₓ)_{0 5}P-based LED structure for the light reflection. In addition, an In_{0 5}(Ga₁₋ₓAlₓ)_{0.5}P barrier is inserted between the p-type In_{0.5}(Ga₁₋ₓAlₓ)_{0 5}P cladding layer and the p-type GaP, AlGaP, or AlGaAs window layer.

In FIG. 2, the LED structure 10 is grown on a Si-doped GaAs substrate 12 with thickness of about 150 to about 250 um and with a 0.2 to 0.4 um Si-doped GaAs buffer layer 14. In the preferable embodiment of the present invention, the GaAs buffer layer 14 is applied to improve the smoothness and uniform surface structure on the GaAs growing surface. Growth of the GaAs buffer layer 14 is essential to obtain a better film's quality with sharp hetero-interfaces including the multi-quantum wells 20 in the LED structure 10. Following the GaAs buffer layer 14, a DBR 16 is grown on the GaAs buffer layer 14 for the purpose of light re-emitting. The light re-emitting layer 16 is made from a material whose prohibited band height is very close to the active region. The materials selection of the light re-emitting layer 16 requires considering lattice matching, band gap and the difference in reflective index, and doping limit of individual reflecting layer 16. Typically, a 10-20 periods of DBR 16 can bring the external quantum efficiency of emitting light up to 1.5 times in brightness of the LED 10 without DBR 16. In AlAs/AlₓGa₁₋ₓAs DBR 16, the wavelength A of reflection is determined by the thickness d of the individual reflecting layer with a function of d=λ/4n, wherein the n represents the reflection index of the individual layer in DBR 16 at a reflection wavelength A The purpose of the DBR 16 is to reflect the emitting light from an active region; the band-gap of the AlₓGa₁₋ₓAs has to be larger than that of the active region to prevent any light adsorption. In addition, the difference in reflective index between individual layers in DBR 16 needs to increase as much as possible to obtain a better efficiency of light re-emitting in DBR 16. However, the DBR 16 also acts as a transition layer for current injection, which requires a high concentration of conducting carriers (>2*10¹⁷/cm²).

Due to the intrinsic limitation of n-type doping in the AlAs-based DBR 16, a limited periods of DBR 16 is expected to obtain a low forward operating voltage for achieving a reflectivity of DBR≧90-95%. Typically, a period of DBR 16 in InGaAlP-based LED 10 is around 10-20. Another candidate used for the DBR 16 is the In_{0.5}(Ga₁₋ₓAlₓ)_{0.5}P-based alloy which can achieve a higher conductivity than the AlAs/AlGaAs-based DBR 16.

Then, the purpose of the n-type In_{0 5}(Ga₁₋ₓAlₓ)_{0.5}P lower cladding layer 18 is utilized for the carrier injection into the active region and the carrier confinement in the active region. The composition of the Al in the n-type In_{0.5}(Ga₁₋ₓAlₓ)_{0 5}P-based cladding layer 18 is approach 0.7 to 1 which depending on the emission wavelength of the active layer 20. The thickness of the n-type lower cladding layer 18 should be thicker than the diffusion length of the injection carriers to prevent the carrier diffusion from the active region into the n-type cladding layer 18.

The “right” n-and p-type doping profiles in the In_{0 5}(Ga₁₋ₓAlₓ)_{0 5}-P based cladding layers 22 leading to a location of p-n junction in the active region is essential for an efficient radiative recombination of electrons and holes in the MQW 20 upon current injection. Any overflow of individual injection carriers would decrease the efficiency of the emitting light due to the misalignment of the p-n junction and creation of non-radiative recombination centers by inter-diffusion of dopants into the active region.

Following the n-type lower cladding layer 18, a strained In_{y}(Ga₁₋ₓAlₓ)_{1-y}P/In_{0 5}(Ga₁₋ₓAlₓ)_{0 5}P multi-quantum well (MQW) 20 is inserted as an active layer 106 (shown in FIG. 1) of the conventional LED 100 between the n- (lower) 18 and p-type (upper) 22 cladding layers. The MQW 20 with an InGaAlP-based superlattice is applied to increase the efficiency in the active region and to reduce the composition of Al in the quantum well for the emission at a short wavelength. The MQW structure 20 will lead to an increase on the efficiency of the emission light for the LED 10. The quantum wells are formed of a well with a narrow band gap and a barrier with a higher band gap. As a result, the electrons and holes are quantized and unable to move freely in the direction of injection current, and can still move freely and recombine in the plane perpendicular to the direction of the injection current. In the MQW 20, the confinement of the carriers at the conduction band pushes the effective conduction band up, and the confinement of the carriers at the valence band pushes the effective band edge downwards. Furthermore, the MQW structure 20 shifts the effective wavelength of the emission to a shorter wavelength. Thus, the advantage for the usage of Al composition in the active region can be reduced greatly, so that, for a particular emitting wavelength, the MQW structure 20 in LED 10 may increase the lifetime of the non-radiative recombination and reduce the absorption of the light emission.

Therefore, the MQW structure 20 can reduce the usage of Al composition and the carrier lifetime of the rediative recombination, so that the quantum efficiency of the LED 10 with a MQW 20 active region can increase greatly, wherein the Al composition x of the In_{0 5}(Ga₁₋ₓAlₓ)_{0.5}P alloy in the MQW 20 has a range from 0 to 0.3 and from the red to yellow-green light emission and needs to conspire with the adjustment on the thickness and number of the quantum wells. In the preferable embodiment of the present invention, in a direct band-gap of the In_{0 5}(Ga₁₋ₓAlₓ)_{0.5}P alloy with x is smaller than 0.3 in the MQW 20, the emission wavelength of the thin quantum well is greatly dependent in the thickness of the well.

As the thickness of the well is decreased in the MQW 20, the quantized carriers in the conduction band push the effective sub-band upwards and the carriers in the valance band push the effective sub-band downwards. The quantized band structure in the MQW 20 is sensitive at a certain range of well thickness of about 1 to 10 nm. As a result, the emission wavelength of electron-hole recombination becomes shorter due to the quantized energy band structure. The typically total thickness of the wells and barriers are between 1 and 10 nm for the In_{0 5}(Ga₁₋ₓAlₓ)_{0.5}P alloy obtained with a periodicity of 10 to 50 for the best light emission efficiency. On the other hand, the internal quantum efficiency of the light emission is also dependent on the thickness ratio of well to barrier. A typical value of the well and barrier thickness ratio is near 0.75 to 1.25 for efficient carrier recombination.

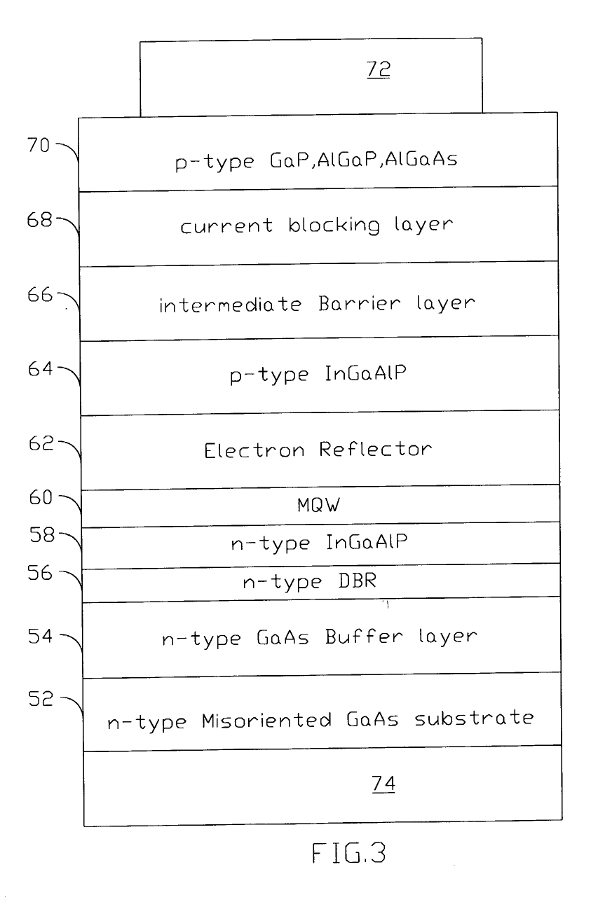

Referring to FIG. 3 shows another device structure of the light emitting diode 50 with a multi-quantum barrier (MQB). The device structure 50 constructed by a GaAs buffer layer 54 on the n-GaAs substrate 52, an DBR 56 on the n-GaAs buffer layer 54, a first cladding layer 58 as an n-type lower cladding layer on the DBR 56, a strained MQW 60 on the first cladding layer 58, an electron reflector 62 on the MQW 60, a second cladding layer 64 as an p-type upper cladding layer on the electron reflector 62, a thin In_{0.5}(Ga₁₋ₓAlₓ)_{0.5}P intermediate barrier layer 66 on the p-type upper cladding layer 64, a p-GaP or p-AlGaAs current spreading layer 68 on the intermediate barrier layer 66, a window layer 70 on the current spreading layer 68, a top metal contact 72 on the top of the window layer 70, and a bottom metal contact 74 on the bottom of the GaAs substrate 52.

The preferred embodiment of the present invention, a thin strained barrier or a multi-layer of electron reflector 62 is inserted in the p-type upper cladding layer 64 to increase the barrier height of the p-type upper cladding layer 64. The electron reflector 62 is grown by OMVPE and requires a precise control on the interface sharpness, layer thickness, and composition. Furthermore, the thin strained barrier layer 62 has an energy gap equal or larger than the energy gap of the cladding layer for improving the efficiency of the light emission. The p-type In_{0.5}Al_{0.5}P barrier of the electron reflector 62 is strained and located very near the active region with an enough thickness and stress to avoid the electron tunneling from the active region. Due to the reflectivity of the electron reflector is increase, so that the efficiency of the light emitting from the active region increases as periods of the In_{0.5}(Ga₁₋ₓAlₓ)_{0 5}P/In_{0.5}Al_{0.5}P superlattice of an electron reflector 62 is also can be increased.

However, this behavior is more significant in an electron reflector 62 with a gradient or steps increase on the thickness of individual In_{0 5}(Ga₁₋ₓAlₓ)_{0.5}P layer within a range from 2 to 5 nm. A variety on the thickness of individual In_{0.5}(Ga₁₋ₓAlₓ)_{0 5}P layer in the electron reflector 62 represents a variety of high electron reflection for a certain range of different incident electron energy from the active region. Therefore, the improvement on the carrier confinement of the “gradient or steps” electron reflector 62 is due to a flexibility to obtain high electron conductivity for a certain range of different electron incident energy. Thus, the variety in electron reflection can be achieved by either a gradient or steps change in layer thickness. In the preferred embodiment of the present invention, the electron reflector 62 containing a strained barrier of In_{0 5}Al_{0 5}P layer followed by an In_{0.5}(Ga₁₋ₓAlₓ)/In_{0 5}Al_{0 5}P superlattice is placed near the active region to reflect the overflowing carriers from the active region.

Next, a p-type In_{0.5}(Ga₁₋ₓAlₓ)_{0 5}P-based upper cladding layer 64 is utilized. The purpose of the p-type In_{0 5}(Ga₁₋ₓAlₓ)_{0 5}P-based upper cladding layer 64 is used for carrier injection into the active region and an effect of carrier confinement in the active region. The thickness of the p-type In_{0.5}(Ga₁₋ₓAlₓ)_{0.5}P-based upper cladding layer 64 should be thicker than the diffusion length of the injection carrier to prevent the carrier diffusion from the active region into the p-type upper cladding layer 64. In addition, the thickness of the p-type In_{0.5}(Ga₁₋ₓAlₓ)_{0.5}P-based upper cladding layer 64 needs to be larger than n-cladding layer 58 that is due to the diffusivity of p-type dopant such as Zn or Mg atoms during the growth of LED structure 50. The typical thickness of the p-type In_{0.5}(Ga₁₋ₓAlₓ)_{0 5}P-based upper cladding layer 64 is of about 0.5 to 1.5 um.

Thereafter, a thin intermediate barrier layer 66 of In_{0 5}(Ga₁₋ₓAlₓ)_{0 5}P with a doping concentration greater than the p-type upper cladding layer 64 which is grown to insure a smooth transition and spreading of the injection carriers. To insure a high conductivity in the thin intermediate barrier layer 66 of In_{0.5}(Ga₁₋ₓAlₓ)_{0 5}P with current spreading on a plane perpendicular to the injection current, the Al composition of about 0.1 to 0.5 in the intermediate barrier layer 66 which is less than in the p-type upper cladding layer 64 and lattice matched to the p-type upper cladding layer 64. It is an important feature of the intermediate current spreading layer 68 is that designed with a thickness of about 50 to 100 nm with a doping concentration higher than that in the p-type upper cladding layer 62 to create a pathway of low resistance on a plane perpendicular to the injection current. Furthermore, the p-type intermediate barrier layer 66 has an energy gap is larger than that in the active region to avoid any absorption of light emitting from the active region.

Since the thickness of this intermediate barrier layer 66 is a very thin and has a doping concentration that is higher than that in the p-type upper cladding layer 64 and lower than that in the window layer 70. Moreover, the intermediate barrier layer 66 can act as a barrier for the current injection along the growth direction and a low resistance path for the current spreading on a plane perpendicular to the growth direction. Therefore, according to abovementioned, the effect of current spreading contributing to the p-type upper cladding layer 64 and active region is controlled via the thickness, composition, and doping level of the In_{0.5}(Ga₁₋ₓAlₓ)_{0.5}P barrier.

It is another important feature of the present invention, in order to maximize the performance of the In_{0 5}(Ga₁₋ₓAlₓ)_{0.5}P-based light emitting diode is to be added window layer 70 on the top of the p-type upper cladding layer 64. Due to the GaP or GaAsP has an energy band-gap transparent to the radiation from the active region in LED structure 50, the GaP or GaAsP can be used as a window layer 70 for a function of the current spreading in LED structure 50. The p-type GaP, AlGaP, or AlGaAs window layer 70 is grown on a GaAs substrate 52 with a misorientation toward <111>A by using “OMVPE” system. The growing surface has a misorientation from the major crystallographic plane. The epitaxial layer is grown by LPE or CVD epitaxial techniques to improve smoothness of deposited film. In the preferred embodiment of the present invention, the III-V compounds of GaP, AlₓGa₁₋ₓ, wherein x is small than 0.1, and Al_{y}Ga_{1-y}As, wherein y is larger than 0.5 and small than 1 which are used as a window layer 70 since they are transparent to the emission wavelength from 650 nm to 565 nm.

Furthermore, the efficiency of the light emission also depends on the thickness of the window layer. The light extraction from the LED structure 50 increases significantly as an increase on the thickness of the window layer 70 due to a wider current spreading area from the window layer 70 and higher light extraction efficiency from the sides of the LED structure 50.

Although specific embodiments have been illustrated and described, it will be obvious to those skilled in the art that various modifications may be made without departing from what is intended to be limited solely by the appended claims.

What is claimed is:

1. A light emitting diode structure, said light emitting diode structure comprising:
a bottom metal electrode contact;
a GaAs substrate of a first conductivity type on said bottom metal electrode contact, wherein said GaAs substrate of said first conductivity type is misoriented with a tilting angle larger than 10 degree toward <111>A;
a light re-emitting layer of said first conductivity type on said GaAs substrate;
a first cladding layer of said first conductivity type on said light re-emitting layer;
an active layer on said first cladding layer of said first conductivity type;
a second cladding layer of a second conductivity type on said active layer, wherein said second conductivity type opposites to said first conductivity type;
a current blocking layer on said second cladding layer;
a window layer on said current blocking layer; and
a top metal electrode contact on said window layer.

2. The light emitting diode structure according to claim 1, wherein said GaAs substrate is misoriented with a tilting angle is of about 15 degree preferably.

3. The light emitting diode structure according to claim 1, wherein said GaAs substrate with thickness of about 150 to about 250 um.

4. The light emitting diode structure according to claim 1, wherein said GaAs substrate with thickness of about 210 um preferably.

5. The light emitting diode structure according to claim 1, further comprising a buffer layer of said first conductivity insert between said GaAs substrate and said light re-emitting layer.

6. The light emitting diode structure according to claim 1, wherein said light re-emitting layer comprises a Distributed Bragg Reflector (DBR).

7. The light emitting diode structure according to claim 6, wherein said Distributed Bragg Reflector comprises an AlAs/AlₓGa₁₋ₓAs— of said first conductivity type.

8. The light emitting diode structure according to claim 6, wherein said Distributed Bragg Reflector comprises an In_{0.5}(Ga₁₋ₓAlₓ)_{0.5}P-based of said second conductivity type.

9. The light emitting diode structure according to claim 1, wherein said active layer comprises a strained and un-doped In_{y}(Ga₁₋ₓAlₓ)_{1-y}P/In_{0.5}(Ga₁₋ₓAlₓ)_{0.5}P.

10. The light emitting diode structure according to claim 1, further comprising an intermediate barrier layer insert between said second cladding layer and said window layer.

11. The light emitting diode structure according to claim 10, wherein said intermediate barrier layer comprises an InGaAlP-based.

12. The light emitting diode structure according to claim 1, wherein said current blocking layer comprises a In_{0.5}(Ga₁₋ₓAlₓ)P layer of said second conductivity type.

13. The light emitting diode structure according to claim 1, wherein said window layer for spreading current in said light emitting diode structure.

14. A light emitting diode structure, said light emitting diode structure comprising:
a bottom metal electrode contact;
a GaAs substrate of a first conductivity type with thickness of about 150 to about 250 um on said bottom metal electrode contact, wherein said GaAs substrate is misoriented a tilting angle larger than 10 degree toward <111>A;
a light re-emitting layer of said first conductivity type on said GaAs substrate;
a first cladding layer of said first conductivity type on said light re-emitting layer;
an active layer on said first cladding layer;
an electron reflector on said active layer;
a second cladding layer of a second conductivity type on said electron reflector, wherein thickness of said second cladding layer is thicker than said first cladding layer, and said second conductivity type opposites to said first conductivity type;
a current blocking layer on said second cladding layer;
a window layer on said current blocking layer, wherein said window layer for spreading current in said light emitting diode structure; and
a top metal electrode contact on said window layer.

15. The light emitting diode structure according to claim 14, wherein said GaAs substrate is misoriented with a tilting angle is of about 15 degree preferably.

16. The light emitting diode structure according to claim 14, wherein said GaAs substrate with thickness of about 210 um preferably.

17. The light emitting diode structure according to claim 14, further comprising a buffer layer of said first conductivity type insert between said GaAs substrate and said light re-emitting layer.

18. The light emitting diode structure according to claim 14, wherein said light re-emitting layer comprises a Distributed Bragg Reflector (DBR).

19. The light emitting diode structure according to claim 18, wherein said Distributed Bragg Reflector comprises an AlAs/AlₓGa₁₋ₓAs— of said first conductivity type.

20. The light emitting diode structure according to claim 18, wherein said Distributed Bragg Reflector comprises an In_{0 5}(Ga₁₋ₓAlₓ)_{0 5}P-based of said second conductivity type.

21. The light emitting diode structure according to claim 14, wherein said active layer comprises a strained and un-doped In_{y}(Ga₁₋ₓAlₓ)_{1-y}P/In_{0 5}(Ga₁₋ₓAlₓ)_{0.5}P multi-quantum well.

22. The light emitting diode structure according to claim 14, wherein said electron reflector comprises In_{y}(Ga₁₋ₓAlₓ)_{1-y}P/In_{0.5}(Ga₁₋ₓAlₓ)_{0.5}P superlattice.

23. The light emitting diode structure according to claim 14, further comprising an intermediate barrier layer insert between said second cladding layer and said current blocking layer.

24. The light emitting diode structure according to claim 23, wherein said intermediate barrier layer comprises InGaAlP-based.

25. The light emitting diode structure according to claim 14, wherein said current blocking layer comprises a In_{0.5}(Ga₁₋ₓAlₓ)P layer of said second conductivity type.
